(19) United States
(12) Patent Application Publication
(10) Pub. No.: US 2020/0052178 A1
(43) Pub. Date: Feb. 13, 2020

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP)

(73) Assignee: TDK CORPORATION, Tokyo (JP)

(21) Appl. No.: 16/509,938

(22) Filed: Jul. 12, 2019

(30) Foreign Application Priority Data
Aug. 8, 2018 (JP) 2018-149563

(51) Int. Cl. H01L 35/02; H01L 35/30; H01L 35/32; H01L 27/16

(52) U.S. Cl. CPC H01L 35/02; H01L 27/16; H01L 35/32; H01L 35/30

(57) ABSTRACT

The device includes heat transfer portions, each of which is configured to thermally connect: one electrode provided on one side of a hot junction side and a cold junction side of each thermoelectric conversion element; and a heat transfer member. A base material has recesses on a second surface side, the recesses being provided so as to be recessed in a range of a region which overlaps with interspaces between other electrodes provided on other side of the hot junction side and the cold junction side of the each thermoelectric conversion element in a plan view. A low thermal expansion layer is provided on a surface side of each of the thermoelectric conversion element facing the heat transfer member or a high thermal expansion layer is provided on a surface side of each of the thermoelectric conversion elements facing the recess.

### BACKGROUND

The disclosure relates to a thermoelectric conversion device. Priority is claimed on Japanese Patent Application No. 2018-149563, filed Aug. 8, 2018, the content of which is incorporated herein by reference.

For example, exhaust heat from internal-combustion engines, combustion devices or the like is lost without being used. For this reason, from the viewpoint of energy saving, use of such exhaust heat has been focused on in recent years. Particularly, research on thermoelectric conversion devices that enable conversion from heat to electricity is actively progressing (see, for example, PCT International Publication No. WO 2011/065185).

Specifically, PCT International Publication No. WO 2011/065185 discloses a thermoelectric conversion module (thermoelectric conversion device) including an insulating substrate, a plurality of thermoelectric conversion material films which are formed of any one thermoelectric conversion material of a p-type and an n-type and are disposed at intervals from each other on a first surface of the insulating substrate, a first electrode and a second electrode formed apart from each other on each of the thermoelectric conversion material films, a first heat transfer member which is disposed on the first surface side of the insulating substrate and is provided with a protrusion that comes into contact with the first electrode, and a second heat transfer member which is disposed on a second surface side of the insulating substrate and is provided with a protrusion that comes into contact with the second surface of the insulating substrate and a region corresponding to the second electrode.

In addition, this thermoelectric conversion module is configured such that the first electrode is formed along one side of the thermoelectric conversion material film, the second electrode is formed along the other side facing one side of the thermoelectric conversion material film, the first electrode is connected to the second electrode on the thermoelectric conversion material film adjacent to one side, and the second electrode is connected to the first electrode on the thermoelectric conversion material film adjacent to the other side.

In order to achieve the improvement of thermoelectric conversion characteristics in the above-described thermoelectric conversion device, it is important to increase a difference in temperature between the hot junction side and the cold junction side of the thermoelectric conversion element. In addition, in order to efficiently use heat from a heat source, heat transferred from the heat source is required to be concentrated on the hot junction side of the thermoelectric conversion element.

For example, in the thermoelectric conversion module disclosed in PCT International Publication No. WO 2011/065185, since heat is transferred through the insulating substrate, heat is released through this insulating substrate, which leads to a problem of a decrease in output.

As a countermeasure to this, the inventors have examined providing a recess on a surface on the opposite side of a surface on which the thermoelectric conversion material film of the insulating substrate is provided, which makes it difficult for heat to be released through the insulating substrate.

However, the inventors have found that, in a case where such a recess is provided, deformation caused by thermal expansion may occur in a plurality of thermoelectric conversion elements provided in a row in the surface of the substrate, and deformation occurring in each of the thermoelectric conversion elements thus becomes non-uniform, which leads to instability of thermal contact between a portion of the electrode and the protrusion (heat transfer portion). Therefore, the inventors have found that, in this case, a decrease in the thermal connection reliability of each thermoelectric conversion element prevents a sufficient output from being obtained.

### SUMMARY

It is desirable to provide a thermoelectric conversion device with improved thermal connection reliability of the thermoelectric conversion element.

(1) The thermoelectric conversion device, including:

a base material having a first surface and a second surface that face each other in a thickness direction;

thermoelectric conversion elements provided in a row in a plane on the first surface side of the base material;

electrodes, each of which is provided on one end side or other end side of each of the thermoelectric conversion elements in a direction of the row of the thermoelectric conversion elements;

a heat transfer member disposed on the first surface side of the base material with an interval from at least a part of the thermoelectric conversion elements; and

heat transfer portions, each of which is configured to thermally connect: one electrode provided on one side of a hot junction side and a cold junction side of each of the thermoelectric conversion elements; and the heat transfer member,

wherein the base material has recesses on the second surface side, the recesses being provided so as to be recessed in a range of a region which overlaps with interspaces between other electrodes provided on other side of the hot junction side and the cold junction side of each of the thermoelectric conversion elements in a plan view, and

a low thermal expansion layer having a lower coefficient of thermal expansion than that of the thermoelectric conversion element is provided on a surface side of each of the thermoelectric conversion elements facing the heat transfer member.

(2) The thermoelectric conversion device, including:

a base material having a first surface and a second surface that face each other in a thickness direction;

thermoelectric conversion elements provided in a row in a plane on the first surface side of the base material;

electrodes, each of which is provided on one end side or other end side of each of the thermoelectric conversion elements in a direction of the row of the thermoelectric conversion elements;

a heat transfer member disposed on the first surface side of the base material with an interval from at least a part of the thermoelectric conversion elements; and

heat transfer portions, each of which is configured to thermally connect: one electrode provided on one side of a hot junction side and a cold junction side of each of the thermoelectric conversion elements; and the heat transfer member,

wherein the base material has recesses on the second surface side, the recesses being provided so as to be recessed in a range of a region which overlaps with interspaces between other electrodes provided on other side of the hot junction side and the cold junction side of each of the thermoelectric conversion elements in a plan view, and

a high thermal expansion layer having a higher coefficient of thermal expansion than that of the thermoelectric conversion element is provided on a surface side of each of the thermoelectric conversion elements facing the recess.

### BRIEF DESCRIPTION OF THE DRAWINGS

FIG. 1 is a perspective plan view illustrating a schematic configuration of a thermoelectric conversion device according to a first embodiment of the disclosure.

FIG. 2 is a cross-sectional view along segment A-A shown in FIG. 1 of the thermoelectric conversion device.

FIG. 3 is an enlarged cross-sectional view illustrating main parts of a surrounded portion B shown in FIG. 2.

FIG. 4 is a cross-sectional view illustrating a state in which each thermoelectric conversion element of the thermoelectric conversion device shown in FIG. 2 is deformed due to thermal expansion.

FIG. 5 is a cross-sectional view illustrating a schematic configuration of a thermoelectric conversion device according to a second embodiment of the disclosure.

FIG. 6 is an enlarged cross-sectional view illustrating main parts of a surrounded portion C shown in FIG. 5.

FIG. 7 is a cross-sectional view illustrating a state in which each thermoelectric conversion element of the thermoelectric conversion device shown in FIG. 5 is deformed due to thermal expansion.

FIG. 8 is a cross-sectional view illustrating a schematic configuration of a thermoelectric conversion device according to a third embodiment of the disclosure.

FIG. 9 is an enlarged cross-sectional view illustrating main parts of a surrounded portion D shown in FIG. 8.

FIG. 10 is a cross-sectional view illustrating a state in which each thermoelectric conversion element of the thermoelectric conversion device shown in FIG. 8 is deformed due to thermal expansion.

FIG. 11 is a cross-sectional view illustrating a schematic configuration of a thermoelectric conversion device according to a fourth embodiment of the disclosure.

FIG. 12 is an enlarged cross-sectional view illustrating main parts of a surrounded portion E shown in FIG. 11.

FIG. 13 is a cross-sectional view illustrating a state in which each thermoelectric conversion element of the thermoelectric conversion device shown in FIG. 11 is deformed due to thermal expansion.

FIG. 14 is a cross-sectional view illustrating a schematic configuration of a thermoelectric conversion device according to a fifth embodiment of the disclosure.

FIG. 15 is an enlarged cross-sectional view illustrating main parts of a surrounded portion F shown in FIG. 14.

FIG. 16 is a cross-sectional view illustrating a state in which each thermoelectric conversion element of the thermoelectric conversion device shown in FIG. 14 is deformed due to thermal expansion.

FIG. 17 is a perspective plan view illustrating a schematic configuration of a thermoelectric conversion device according to a sixth embodiment of the disclosure.

FIG. 18 is a cross-sectional view illustrating a schematic configuration of the thermoelectric conversion device shown in FIG. 17.

FIG. 19 is a cross-sectional view illustrating a schematic configuration of a thermoelectric conversion device according to a seventh embodiment of the disclosure.

### DETAILED DESCRIPTION

Hereinafter, embodiments of the disclosure will be described in detail with reference to the accompanying drawings.

Meanwhile, in the drawings used in the following description, the feature portions of the disclosure may be enlarged for convenience in order to make the features thereof easier to understand, and the dimensional ratios and the like of the components are not necessarily the same as those in reality. In addition, materials and the like exemplified in the following description are merely illustrative, and the present invention is not necessarily limited thereto, and can be appropriately modified and implemented without departing from the scope of the disclosure.

### First Embodiment

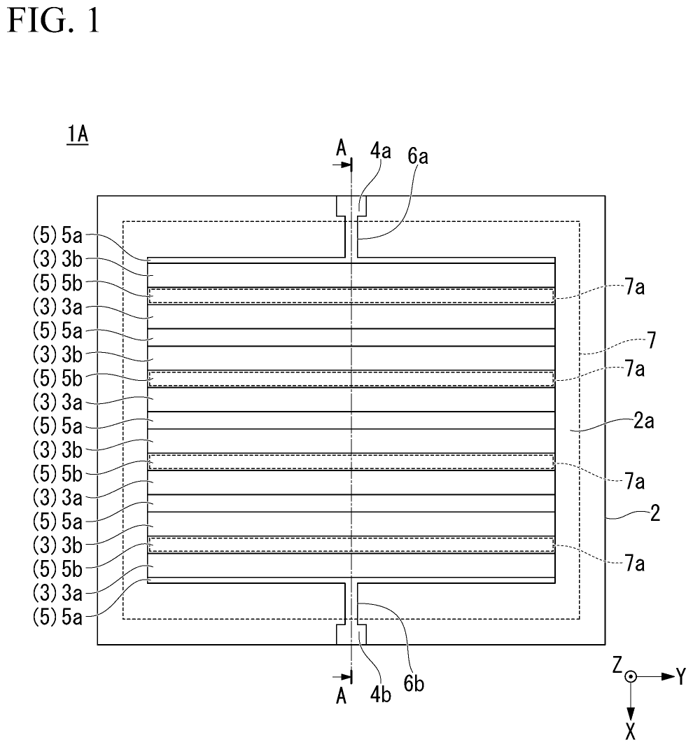

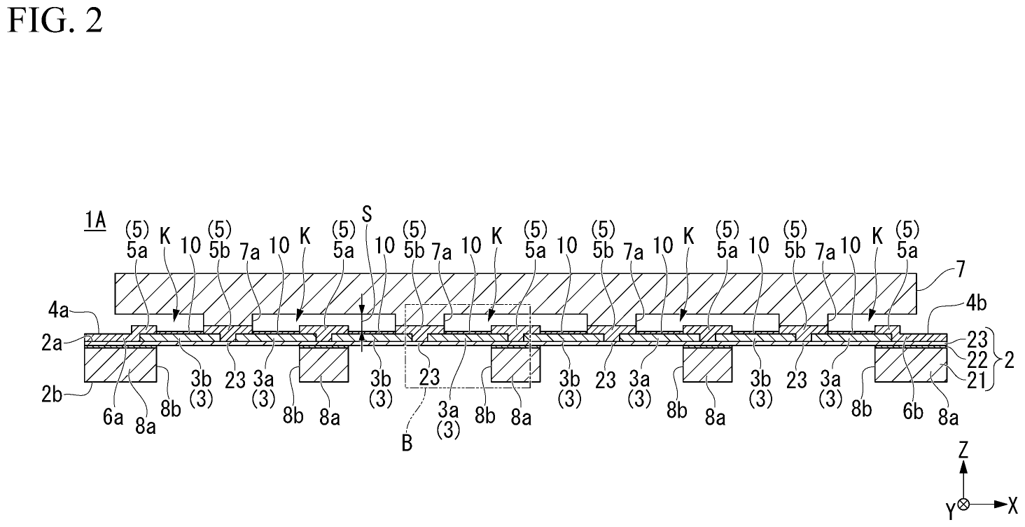

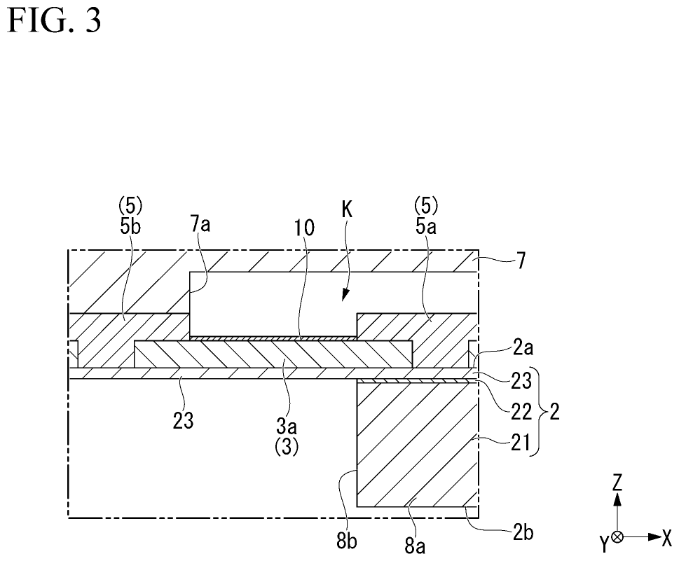

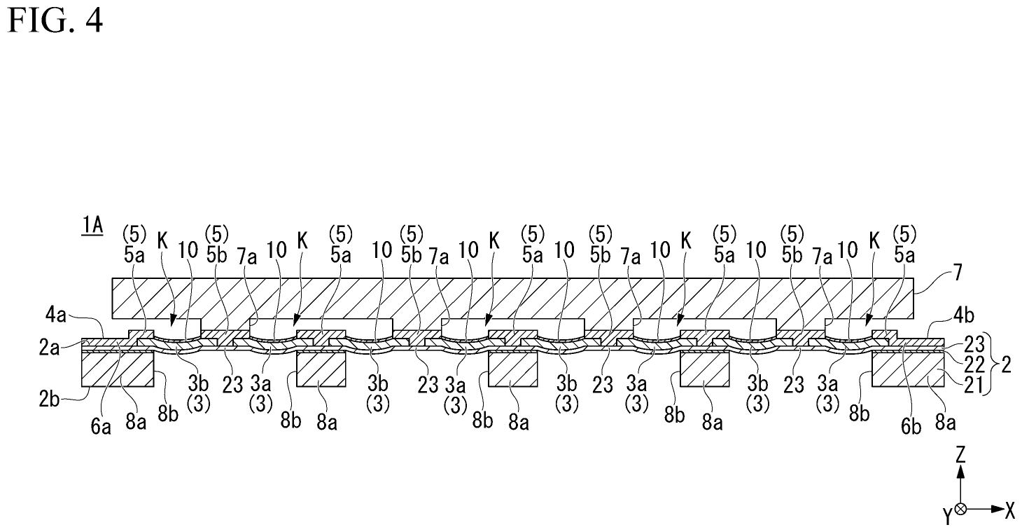

First, as a first embodiment of the disclosure, for example, a thermoelectric conversion device 1A shown in FIGS. 1 to 4 will be described. Meanwhile, FIG. 1 is a perspective plan view illustrating a schematic configuration of a thermoelectric conversion device 1A. FIG. 2 is a cross-sectional view along segment A-A shown in FIG. 1 of the thermoelectric conversion device 1A. FIG. 3 is an enlarged cross-sectional view illustrating main parts of a surrounded portion B shown in FIG. 2. FIG. 4 is a cross-sectional view illustrating a state in which each thermoelectric conversion element 3 warps due to heat transferred to each thermoelectric conversion element 3.

In addition, in the drawings shown below, an XYZ orthogonal coordinate system is set, and it is assumed that an X-axis direction is defined as a first direction in a specific plane of the thermoelectric conversion device 1A, a Y-axis direction is defined as a second direction orthogonal to the first direction in the specific plane of the thermoelectric conversion device 1A, and a Z-axis direction is defined as a third direction (thickness direction/height direction) orthogonal to the specific surface of the thermoelectric conversion device 1A.

As shown in FIGS. 1 and 2, the thermoelectric conversion device 1A of the present embodiment has a structure in which a plurality of (eight in the present embodiment) thermoelectric conversion elements 3 disposed in a row on the surface of a substrate 2 are connected in series to each other between a pair of terminals 4a and 4b.

The substrate 2 is formed of an insulating base material having a first surface (an upper surface in the present embodiment) 2a and a second surface (a lower surface in the present embodiment) 2b that face each other in its thickness direction. In the present embodiment, a silicon-on-insulator (SOI) substrate 20 is used as the substrate 2.

The SOI substrate 20 has a structure in which a thin-film silicon (Si) layer 23 serving as an SOI layer (device layer) is formed on the surface of a silicon (Si) substrate 21 serving as a support substrate with a silicon oxide (SiO₂) layer 22 serving as a buried insulating layer (BOX (Buried OXide) layer) interposed therebetween.

In addition, as the substrate 2, it is preferable to use a high-resistance silicon (Si) substrate having, for example, a sheet resistance of 10Ω or more in addition to the above-described SOI substrate 20. The sheet resistance of the substrate 2 is set to be 10Ω or more, so that it is possible to prevent an electric short-circuit from occurring between a plurality of thermoelectric conversion elements 3.

Meanwhile, examples of the substrate 2 capable of being used include a ceramic substrate, a glass substrate, other high-resistance single-crystal substrates, and the like in addition to the SOI substrate 20 or the high-resistance Si substrate described above.

Further, even when a low-resistance substrate having a sheet resistance of 10Ω or less is used, the substrate 2 capable of being used has a high-resistance material disposed between this low-resistance substrate and a thermoelectric conversion element 3.

In a state where, out of a first direction and a second direction that intersect each other (that are orthogonal to each other in the present embodiment) in a plane (specific plane) on the first surface 2a side of the substrate 2, the first direction is defined as a lateral direction and the second direction is defined as a longitudinal direction, the plurality of thermoelectric conversion elements 3 are disposed in a row at a constant distance in the first direction. In addition, each of the thermoelectric conversion elements 3 is formed in a right-angled quadrilateral shape (a rectangular shape in the present embodiment) with the same size in a plan view.

The plurality of thermoelectric conversion elements 3 have a configuration in which a first thermoelectric conversion element (one thermoelectric conversion element) 3a formed of any one (an n-type semiconductor in the present embodiment) of a p-type semiconductor and an n-type semiconductor and a second thermoelectric conversion element (the other thermoelectric conversion element) 3b formed of the other (a p-type semiconductor in the present embodiment) of a p-type semiconductor and an n-type semiconductor are alternately disposed in a row.

A multilayer film of an n-type silicon (Si) film and an n-type silicon germanium (SiGe) alloy film which are doped with, for example, high-concentration (10¹⁸ to 10¹⁹ cm⁻³) antimony (Sb) can be used in the first thermoelectric conversion element 3a. In the first thermoelectric conversion element 3a formed of an n-type semiconductor, a current flows from the cold junction side toward the hot junction side.

A multilayer film of a p-type silicon (Si) film and a p-type silicon germanium (SiGe) alloy film which are doped with, for example, high-concentration (10¹⁸ to 10¹⁹ cm⁻³) boron (B) can be used in the second thermoelectric conversion element 3b. In the second thermoelectric conversion element 3b formed of a p-type semiconductor, a current flows from the hot junction side toward the cold junction side.

Meanwhile, the thermoelectric conversion element 3 is not necessarily limited to the multilayer film formed of a p-type or n-type semiconductor described above, and may be a single layer film formed of a p-type or n-type semiconductor.

In addition, an oxide-based semiconductor can also be used as a semiconductor. In addition, a thermoelectric conversion film formed of an organic polymer film, a metal film or the like can be used. Further, the thermoelectric conversion element 3 to be used may be a bulk without being limited to the above-described thermoelectric conversion film.

The thermoelectric conversion device 1A of the present embodiment includes a plurality of (nine in the present embodiment) electrodes 5 provided on one end side and the other end side of each thermoelectric conversion element 3 in the direction (first direction) of the row of the plurality of thermoelectric conversion elements 3.

The plurality of electrodes 5 are disposed on the first surface 2a of the substrate 2, and are disposed in a state where the electrodes are in contact with the lateral side of one end side and the lateral side of the other end side that face each other in the first direction of the thermoelectric conversion element 3 and an upper surface along the lateral side of one end side and the lateral side of the other end side of the thermoelectric conversion element 3.

Meanwhile, the plurality of electrodes 5 may be configured to be disposed on an upper surface along the lateral side of one end side and the lateral side of the other end side that face each other in the first direction of the thermoelectric conversion element 3. In addition, the plurality of electrodes 5 may be configured to be disposed on the first surface 2a of the substrate 2 in a state where the electrodes are in contact with the lateral side of one end side and the lateral side of the other end side that face each other in the first direction of the thermoelectric conversion element 3.

The plurality of electrodes 5 are formed in right-angled quadrilateral shapes (rectangular shapes in the present embodiment) with the same size in a plan view throughout the entire region in the longitudinal direction (second direction) of the thermoelectric conversion element 3. For example, copper (Cu), gold (Au) or the like that has high electric conductivity and high thermal conductivity and has a tendency to perform profiling can be suitably used in the electrode 5.

The plurality of electrodes 5 have a configuration in which five first electrodes (other-side electrodes) 5a serving as cold-junction-side electrodes and four second electrodes (one-side electrodes) 5b serving as hot-junction-side electrodes are alternately disposed in a row. The plurality of thermoelectric conversion elements 3 are disposed between the first electrodes 5a and the second electrodes 5b which are alternately next to each other in the direction of the row of the plurality of electrodes 5, and are electrically connected to the first electrodes 5a and the second electrodes 5b.

The first electrode 5a is disposed on one end side (the +X side in the present embodiment) of each first thermoelectric conversion element 3a and the other end side (the −X side in the present embodiment) of each second thermoelectric conversion element 3b. On the other hand, the second electrode 5b is disposed on the other end side (the −X side in the present embodiment) of each first thermoelectric conversion element 3a and one end side (the +X side in the present embodiment) of each second thermoelectric conversion element 3b.

In the first thermoelectric conversion element 3a formed of an n-type semiconductor, a current flows from the first electrode 5a side serving as a cold junction toward the second electrode 5b side serving as a hot junction. On the other hand, in the second thermoelectric conversion element 3b formed of a p-type semiconductor, a current flows from the second electrode 5b side serving as a hot junction toward the first electrode 5a side serving as a cold junction.

Therefore, in the thermoelectric conversion device 1A of the present embodiment, the direction of a current flowing to the first thermoelectric conversion element 3a and the direction of a current flowing to the second thermoelectric conversion element 3b are set to the same direction as each other.

The pair of terminals 4a and 4b are disposed on the first surface 2a of the substrate 2. One terminal 4a is electrically connected through a first wiring 6a to a first electrode 5a disposed on the −X side of the thermoelectric conversion element 3 (the second thermoelectric conversion element 3b in the present embodiment) which is located on the other endmost side (the −X side) in the direction (first direction) of the row of the thermoelectric conversion elements 3. In the present embodiment, the one terminal 4a is formed in a right-angled quadrilateral shape (a rectangular shape in the present embodiment) in a plan view, and is formed integrally with the first wiring 6a extending from the central portion of the first electrode 5a in its longitudinal direction (second direction) to a side (the −X side) located further outside than this first electrode 5a.

On the other hand, the other terminal 4b is electrically connected through a second wiring 6b to a first electrode 5a disposed on the +X side of the thermoelectric conversion element 3 (the first thermoelectric conversion element 3a in the present embodiment) which is located on one endmost side (the +X side) in the direction (first direction) of the row of the thermoelectric conversion element 3. In the present embodiment, the other terminal 4b is formed in a right-angled quadrilateral shape (a rectangular shape in the present embodiment) in a plan view, and is formed integrally with the second wiring 6b extending from the central portion of the first electrode 5a in its longitudinal direction (second direction) to a side (the +X side) located further outside than this first electrode 5a.

Meanwhile, since the pair of terminals 4a and 4b, the first wiring 6a and the second wiring 6b are formed integrally with the first electrode 5a, it is possible to use the same materials as those exemplified in the above-described electrode 5.

The thermoelectric conversion device 1A of the present embodiment includes a heat transfer plate 7 which is thermally connected to the thermoelectric conversion element 3 with a heat transfer portion 7a interposed therebetween. In the thermoelectric conversion device 1A, the heat transfer plate 7 is disposed so as to serve as a high-temperature (heat source) side, and the substrate 2 is disposed so as to serve as a low-temperature (heat dissipation/cooling) side.

The heat transfer plate 7 is a heat transfer member on the high-temperature (heat source) side, and is formed of a material having higher thermal conductivity than that of air, preferably a material having higher thermal conductivity than that of the substrate 2. As such a material of the heat transfer plate 7, a metal is preferably used, and especially among metals, for example, aluminum (Al), copper (Cu) or the like that has high thermal conductivity and has a tendency to perform profiling can be suitably used. In addition, as the materials of the heat transfer plate 7, ceramic materials such as an aluminum oxide (Al₂O₃) can also be used. In addition, the heat transfer plate 7 may be constituted by a plurality of members.

The heat transfer plate 7 is disposed at a distance S from each thermoelectric conversion element 3 and the first electrode 5a so as to face the surface (the first surface 2a in the present embodiment) side of the substrate 2 on which the thermoelectric conversion element 3 is provided. Meanwhile, the distance S may be partially different due to a difference in the thicknesses of the thermoelectric conversion element 3 and the first electrode 5a.

In the case of this configuration, heat transferred from a heat source to be described later to the heat transfer plate 7 is intensively transferred to the second electrode 5b serving as a hot junction through the heat transfer portion 7a. On the other hand, it becomes difficult for the heat transferred from the heat source to the heat transfer plate 7 to be transferred to the first electrode 5a serving as a cold junction. This makes it possible to obtain a high output by obtaining a great difference in temperature between the hot junction and the cold junction each thermoelectric conversion element 3.

The heat transfer portion 7a is constituted by a protrusion projected from one surface side out of surfaces of the heat transfer plate 7 and the second electrode 5b which face each other. The heat transfer portion 7a of the present embodiment is constituted by a protrusion projected from the position of the heat transfer plate 7 facing each second electrode 5b toward a downward direction (−Z direction) which is the thermoelectric conversion element 3 side. This protrusion (heat transfer portion 7a) can have the same materials as those exemplified in the heat transfer plate 7 used therein. In addition, the heat transfer portion 7a can be formed integrally with the heat transfer plate 7.

Each heat transfer portion 7a has a right-angled quadrilateral shape (a rectangular shape in the present embodiment) in a plan view, and is projected inclusive of a range of overlapping each second electrode 5b in a plan view. Each protrusion constituting the heat transfer portion 7a is in a state in which each tip is butted to each second electrode 5b. Thereby, the heat transfer plate 7 is thermally connected to the hot junction side (the −X side of the first thermoelectric conversion element 3a and the +X side of the second thermoelectric conversion element 3b) of the thermoelectric conversion element 3 with the protrusion (heat transfer portion 7a) interposed therebetween.

In addition, the tip of each heat transfer portion 7a is thermally connected to each second electrode 5b in a state of being electrically insulated therefrom with an insulating layer (not shown) interposed therebetween.

The insulating layer constitutes a portion of the heat transfer portion 7a, and an insulating material such as, for example, an aluminum oxide (Al₂O₃), a silicon oxide (SiO₂), a silicon nitride (SiN), or an aluminum nitride (AlN) which has higher thermal conductivity than that of air can be used therein. In addition, for example, a UV-curable resin, a silicone-based resin, heat-conductive grease (such as, for example, silicone-based grease or non-silicone-based grease containing a metal oxide) or the like can be used therein. Meanwhile, in a case where electrical insulation between the tip of the heat transfer portion 7a and the second electrode 5b does not matter, the tip of the heat transfer portion 7a and the second electrode 5b may be directly connected to each other without providing the above-described insulating layer.

In addition, the heat transfer portion 7a is not limited to a case in which the heat transfer portion is constituted by the protrusion projected from the above-described heat transfer plate 7 side, and can also be constituted by a protrusion projected from the second electrode 5b side toward an upward direction (+Z direction) which is the heat transfer plate 7 side. Such a protrusion can be formed, for example, by making the thickness of the second electrode 5b larger than the thickness of the thermoelectric conversion element 3, and the heat transfer plate 7 and the thermoelectric conversion element 3 (second electrode 5b) can also be thermally connected to each other with such a protrusion interposed therebetween. Further, a separate member (including the above insulating layer) that thermally connects the heat transfer plate 7 to the thermoelectric conversion element 3 (second electrode 5b) can also be provided as the heat transfer portion 7a.

A space K serving as an air layer is provided between the substrate 2 and the heat transfer plate 7. In addition, the space K is partitioned between the heat transfer portions 7a next to each other. That is, the space K is provided between each thermoelectric conversion element 3 and first electrode 5a and the heat transfer plate 7. This space K has a function of cutting off the conduction of heat (insulating heat). Since this makes it more difficult for the heat transferred from the heat source to the heat transfer plate 7 to be transferred to the first electrode 5a, it is possible to obtain a high output while increasing a difference in temperature between the hot junction and the cold junction of each thermoelectric conversion element 3 to be described later.

Meanwhile, the thermoelectric conversion device 1A of the present embodiment can also be configured such that the above-described space K is filled with a low thermal conductive material having lower thermal conductivity than that of the heat transfer portion 7a.

The thermoelectric conversion device 1A of the present embodiment has a configuration in which, in the substrate 2, the thickness of a portion facing the at least first electrode 5a serving as a cold-junction-side electrode becomes larger than the thickness of a portion facing the second electrode 5b serving as at least a hot-junction-side electrode.

Specifically, the first surface 2a of the substrate 2 is planar, while the second surface 2b of the substrate 2 is provided with a plurality of (five in the present embodiment) protrusions 8a and a plurality of (four in the present embodiment) recesses 8b which are lined up alternately in the second direction.

The plurality of protrusions 8a are projected at a constant height inclusive of a range of overlapping each first electrode 5a in a plan view. The plurality of recesses 8b are recessed at a constant depth over between the plurality of protrusions 8a. That is, the plurality of recesses 8b are recessed in a range of a regions overlaps with interspaces between a plurality of first electrodes 5a in a plan view.

Thereby, the thickness of a portion of the substrate 2 provided with the protrusion 8a is larger than the thickness of a portion provided with the recess 8b. Meanwhile, the protrusion 8a located on both ends in the second direction extends to both ends of the second surface 2b in the second direction at a constant height.

In the present embodiment, as shown in an enlarged view in FIG. 3, the recess 8b having a depth reaching the thin-film Si layer 23 is provided. That is, the thin-film Si layer 23 is located at the bottom of the recess 8b. In the substrate 2 using the SOI substrate 20, the Si substrate 21 of a region corresponding to the recess 8b is removed from the second surface 2b side by performing pattern etching using the SiO₂ layer 22 as an etching stopper. Thereafter, the recess 8b having a depth reaching the thin-film Si layer 23 is formed by removing the SiO₂ layer 22 of a region corresponding to the recess 8b.

In the thermoelectric conversion device 1A of the present embodiment, a low thermal expansion layer 10 is provided on the surface (upper surface in the present embodiment) side of each thermoelectric conversion element 3 facing the heat transfer plate 7. The low thermal expansion layer 10 is formed of a material having a lower coefficient of thermal expansion than that of the thermoelectric conversion element 3. Examples of materials of such a low thermal expansion layer 10 include a silicon oxide (SiO₂: 0.51×10⁻⁶ to 0.58×10⁻⁶), a silicon nitride (Si₃N₄: 2.8×10⁻⁶ to 3.5×10⁻⁶), an aluminum oxide (Al₂O₃: 7.2×10⁻⁶), and the like. Meanwhile, numerical values within parentheses of the above materials indicate the coefficient of thermal expansion [1/K] of each material. Regarding the low thermal expansion layer 10, a material having a lower coefficient of thermal expansion than that of the thermoelectric conversion element 3 can be selected and used from the above materials and the like.

On the other hand, examples of the coefficient of thermal expansion [1/K] of the thermoelectric conversion element 3 include a silicon (Si)-based thermoelectric conversion material (Si: 2.4×10⁻⁶ to 2.6×10⁻⁶), a silicon (Si)-germanium (Ge)-based thermoelectric conversion material (Si₁₋ₓGeₓ(0<x<1): 3×10⁻⁶ to 5×10⁻⁶), and a bismuth (Bi)-tellurium (Te)-based thermoelectric conversion material (Bi₁₋ₓTeₓ(0<x<1): 13×10⁻⁶ to 14×10⁻⁶).

The low thermal expansion layer 10 is formed in a right-angled quadrilateral shape (a rectangular shape in the present embodiment) in a plan view on the surface of each thermoelectric conversion element 3. In the present embodiment, the low thermal expansion layer 10 is provided between the first electrode 5a and the second electrode 5b so as to cover the upper surface of the thermoelectric conversion element 3.

In addition, it is preferable that the thickness of the low thermal expansion layer 10 be smaller than the thickness of the thermoelectric conversion element 3.

By reducing the thickness of the low thermal expansion layer 10, it is possible to suppress the conduction of heat through this low thermal expansion layer 10.

Specifically, the thickness of the low thermal expansion layer 10 is preferably equal to or greater than 1/200 times and equal to or less than ⅕ times (0.005 to 0.2 times), and more preferably equal to or greater than 1/100 times and equal to or less than 1/10 times (0.01 to 0.1 times) the thickness of the thermoelectric conversion element 3. Thereby, while suppressing the conduction of heat through the low thermal expansion layer 10, the deformation direction of the thermoelectric conversion element 3 when the thermoelectric conversion element 3 to be described later is deformed due to thermal expansion can be controlled by the low thermal expansion layer 10.

In addition, it is preferable that the low thermal expansion layer 10 be formed of a material having lower thermal conductivity than that of the thermoelectric conversion element 3. This makes it possible to suppress the conduction of heat through the low thermal expansion layer 10.

Meanwhile, the thermal conductivities [W/mK] of the materials exemplified in the above-described low thermal expansion layer 10 are as follows: silicon oxide (SiO₂: 1.38), silicon nitride (Si₃N₄: 20 to 28), and aluminum oxide (Al₂O₃: 25 to 36).

On the other hand, the thermal conductivities [W/mK] of the materials exemplified in the above-described thermoelectric conversion element 3 are as follows: silicon (Si)-based thermoelectric conversion material (Si: 148), silicon (Si)-germanium (Ge)-based thermoelectric conversion material (Si₁₋ₓGeₓ(0<x<1): 5 to 100), and bismuth (Bi)-tellurium (Te)-based thermoelectric conversion material (Bi₁₋ₓTeₓ(0<x<1): 1 to 2).

In the thermoelectric conversion device 1A of the present embodiment having such a configuration, the heat transferred from the heat source (not shown) to the heat transfer plate 7 is transferred to the second electrode 5b through the heat transfer portion 7a, so that the second electrode 5b side of each thermoelectric conversion element 3 is relatively higher in temperature than the first electrode 5a side, and a difference in temperature occurs between the first electrode 5a and the second electrode 5b of each thermoelectric conversion element 3.

Thereby, the movement of electric charge (carrier) occurs between the first electrode 5a and the second electrode 5b of each thermoelectric conversion element 3. That is, an electromotive force (voltage) due to a Seebeck effect is generated between the first electrode 5a and the second electrode 5b of each thermoelectric conversion element 3.

Here, an electromotive force (voltage) generated in one thermoelectric conversion element 3 is low, but the first thermoelectric conversion element 3a and the second thermoelectric conversion element 3b are alternately connected in series to each other between the pair of terminals 4a and 4b. Therefore, a relatively high voltage can be extracted from between the pair of terminals 4a and 4b as the total electromotive force.

Incidentally, in the thermoelectric conversion device 1A of the present embodiment, the low thermal expansion layer 10 having a lower coefficient of thermal expansion than that of the thermoelectric conversion element 3 is provided on the surface side of each thermoelectric conversion element 3 described above which faces the heat transfer plate 7. In the case of this configuration, as shown in FIG. 4, the heat transferred from the heat source to the heat transfer plate 7 is transferred to each thermoelectric conversion element 3 through the heat transfer portion 7a, so that each thermoelectric conversion element 3 is deformed due to thermal expansion between the first electrode 5a and the second electrode 5b.

In this case, each thermoelectric conversion element 3 is brought into a warped state in the same direction as each other between the first electrode 5a and the second electrode 5b due to a difference in the coefficient of thermal expansion with the low thermal expansion layer 10 provided on its upper surface. That is, since the coefficient of thermal expansion of the thermoelectric conversion element 3 is higher than that of the low thermal expansion layer 10, one end side and the other end side of each thermoelectric conversion element 3 are curved toward the heat transfer plate 7 side. Simultaneously, the second electrode 5b butted to the heat transfer portion 7a of the heat transfer plate 7 is pressed against the heat transfer portion 7a side.

Thereby, in the thermoelectric conversion device 1A of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

### Second Embodiment

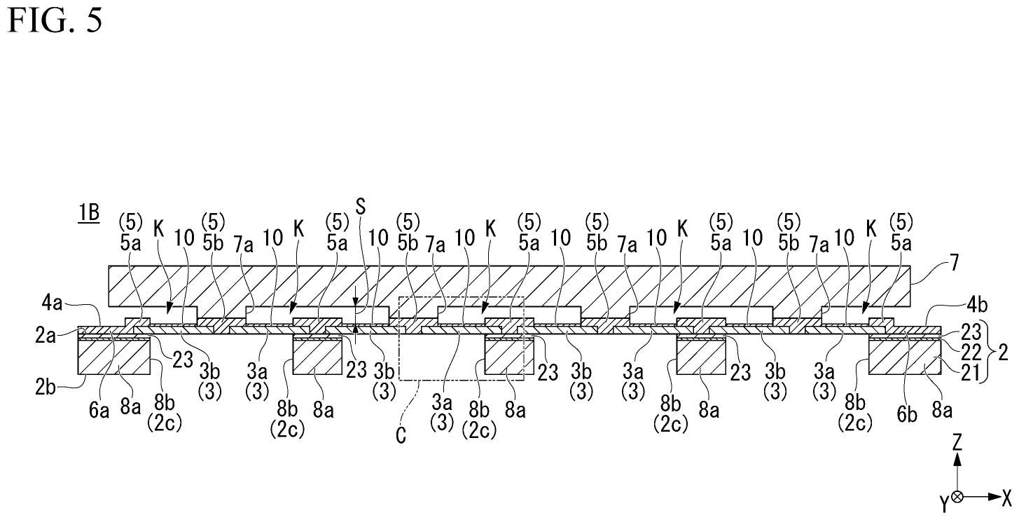

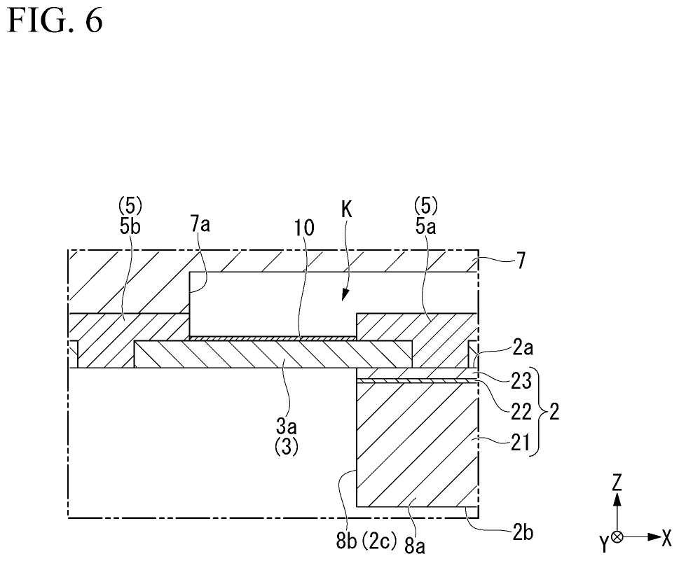

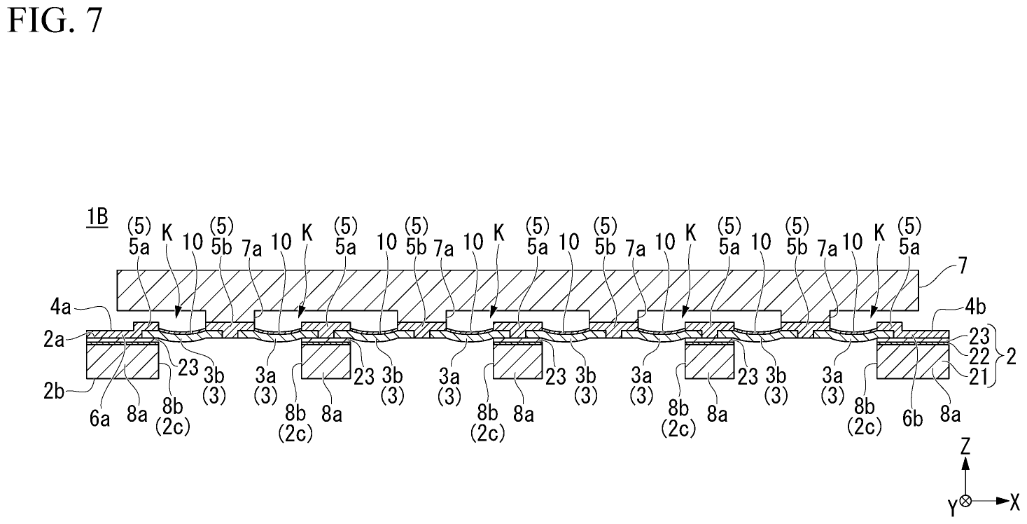

Next, as a second embodiment of the disclosure, for example, a thermoelectric conversion device 1B shown in FIGS. 5 to 7 will be described. Meanwhile, FIG. 5 is a cross-sectional view illustrating a schematic configuration of the thermoelectric conversion device 1B. In addition, FIG. 5 is a cross-sectional view of the thermoelectric conversion device 1B corresponding to segment A-A shown in FIG. 1. FIG. 6 is an enlarged cross-sectional view illustrating main parts of a surrounded portion C shown in FIG. 5. FIG. 7 is a cross-sectional view illustrating a state in which each thermoelectric conversion element 3 of the thermoelectric conversion device 1B is deformed due to thermal expansion. In addition, in the following description, the same parts as those in the above thermoelectric conversion device 1A will not be described, and are assumed to be denoted by the same reference numerals and signs in the drawings.

As shown in FIG. 5, the thermoelectric conversion device 1B of the present embodiment has basically the same configuration as that of the above thermoelectric conversion device 1A, except that at least a portion of the thermoelectric conversion element 3 is located at the bottom of the above-described recess 8b.

Specifically, as shown in an enlarged view in FIG. 6, the thermoelectric conversion device 1B of the present embodiment is provided with the recess 8b having a depth reaching the thermoelectric conversion element 3. That is, in this thermoelectric conversion device 1B, a region corresponding to the recess 8b is provided with a hole portion 2c penetrating through the substrate 2, so that a portion of the thermoelectric conversion element 3 and the first electrode 5a are located (exposed) at the bottom of the recess 8b.

In addition, in the substrate 2 using the SOI substrate 20, the Si substrate 21 of a region corresponding to the recess 8b is removed from the second surface 2b side by performing pattern etching using the SiO₂ layer 22 as an etching stopper. Thereafter, the recess 8b having a depth reaching the thermoelectric conversion element 3 is formed by removing the SiO₂ layer 22 and the thin-film Si layer 23 of a region corresponding to the recess 8b.

In the thermoelectric conversion device 1B of the present embodiment, the low thermal expansion layer 10 having a lower coefficient of thermal expansion than that of the thermoelectric conversion element 3 is provided on the surface side of each thermoelectric conversion element 3 described above which faces the heat transfer plate 7. In the case of this configuration, as shown in FIG. 7, the heat transferred from the heat source to the heat transfer plate 7 is transferred to each thermoelectric conversion element 3 through the heat transfer portion 7a, so that each thermoelectric conversion element 3 is deformed due to thermal expansion between the first electrode 5a and the second electrode 5b.

In this case, each thermoelectric conversion element 3 is brought into a warped state in the same direction as each other between the first electrode 5a and the second electrode 5b due to a difference in the coefficient of thermal expansion with the low thermal expansion layer 10 provided on its surface. That is, since the coefficient of thermal expansion of the thermoelectric conversion element 3 is higher than that of the low thermal expansion layer 10 provided on the surface of each thermoelectric conversion element 3, one end side and the other end side of each thermoelectric conversion element 3 are curved toward the heat transfer plate 7 side. Simultaneously, the second electrode 5b butted to the heat transfer portion 7a of the heat transfer plate 7 is pressed against the heat transfer portion 7a side.

Thereby, in the thermoelectric conversion device 1B of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

In addition, in the thermoelectric conversion device 1B of the present embodiment, the recess 8b having a depth reaching the above-described thermoelectric conversion element 3 is provided, so that a portion of the thermoelectric conversion element 3 and the first electrode 5a are located (exposed) at the bottom of this recess 8b. In this case, it is possible to prevent heat transferred from the heat source to the heat transfer plate 7 from being released from the heat transfer portion 7a through the substrate 2 to the cold junction side of the thermoelectric conversion element 3. Thereby, in the thermoelectric conversion device 1B of the present embodiment, it is possible to obtain a high output while increasing a difference in temperature between the hot junction and the cold junction of each thermoelectric conversion element 3.

### Third Embodiment

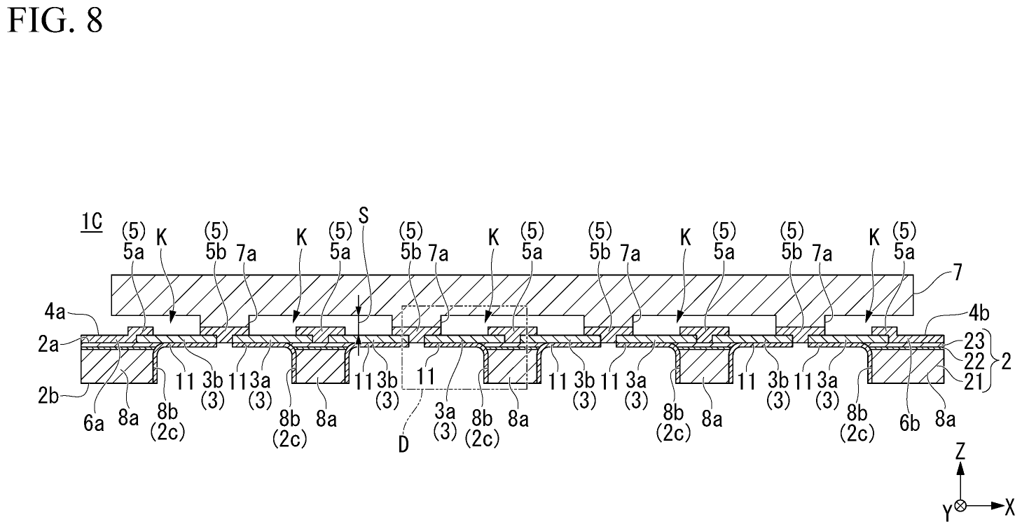

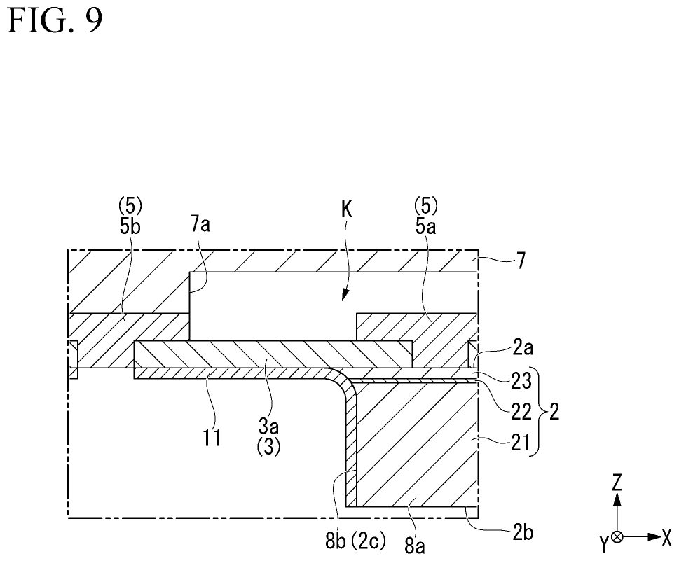

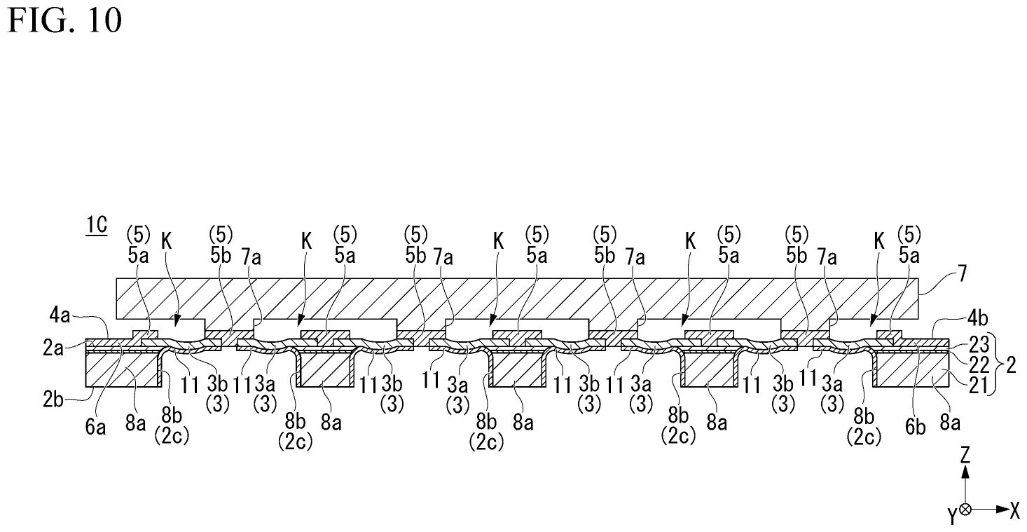

Next, as a third embodiment of the disclosure, for example, a thermoelectric conversion device 1C shown in FIGS. 8 to 10 will be described. Meanwhile, FIG. 8 is a cross-sectional view illustrating a schematic configuration of the thermoelectric conversion device 1C. In addition, FIG. 8 is a cross-sectional view of the thermoelectric conversion device 1C corresponding to segment A-A shown in FIG. 1. FIG. 9 is an enlarged cross-sectional view illustrating main parts of a surrounded portion D shown in FIG. 8. FIG. 10 is a cross-sectional view illustrating a state in which each thermoelectric conversion element 3 of the thermoelectric conversion device 1C is deformed due to thermal expansion. In addition, in the following description, the same parts as those in the above thermoelectric conversion device 1B will not be described, and are assumed to be denoted by the same reference numerals and signs in the drawings.

As shown in FIG. 8, the thermoelectric conversion device 1C of the present embodiment has basically the same configuration as that of the above thermoelectric conversion device 1B, except that a high thermal expansion layer 11 is provided instead of the above-described low thermal expansion layer 10.

Specifically, as shown in an enlarged view in FIG. 9, the thermoelectric conversion device 1C of the present embodiment has a configuration in which the high thermal expansion layer 11 is provided on the surface (lower surface in the present embodiment) side of each thermoelectric conversion element 3 facing the recess 8b. The high thermal expansion layer 11 is formed of a material having a higher coefficient of thermal expansion than that of the thermoelectric conversion element 3. Examples of materials of such a high thermal expansion layer 11 include an aluminum oxide (Al₂O₃: 7.2×10⁻⁶), tin (Sn: 23×10⁻⁶), a magnesium (Mg) alloy (26 to 28×10⁻⁶), a polyimide (27×10⁻⁶), and the like. Meanwhile, numerical values within parentheses of the above materials indicate the coefficient of thermal expansion [1/K] of each material. Regarding the high thermal expansion layer 11, a material having a higher coefficient of thermal expansion than that of the thermoelectric conversion element 3 can be selected and used from the above materials and the like.

In the thermoelectric conversion device 1C of the present embodiment, similarly to the above thermoelectric conversion device 1B, a region corresponding to the recess 8b is provided with a hole portion 2c penetrating through the substrate 2, so that a portion of the thermoelectric conversion element 3 and the first electrode 5a are located at the bottom of the recess 8b.

The high thermal expansion layer 11 of the present embodiment is located at the bottom of this recess 8b, and is provided so as to cover the bottom of the recess 8b including the lower surface of the thermoelectric conversion element 3 and the lateral side of the recess 8b. On the other hand, the high thermal expansion layer 11 is partitioned between the thermoelectric conversion elements 3 (at a position corresponding to the first electrode 5a) located at the bottom of the recess 8b.

In addition, it is preferable that the thickness of the high thermal expansion layer 11 be smaller than the thickness of the thermoelectric conversion element 3.

By reducing the thickness of the high thermal expansion layer 11, it is possible to suppress the conduction of heat through this high thermal expansion layer 11.

Specifically, the thickness of the high thermal expansion layer 11 is preferably equal to or greater than 1/200 times and equal to or less than ⅕ times (0.005 to 0.2 times), and more preferably equal to or greater than 1/100 times and equal to or less than 1/10 times (0.01 to 0.1 times) the thickness of the thermoelectric conversion element 3. Thereby, while suppressing the conduction of heat through the high thermal expansion layer 11, the deformation direction of the thermoelectric conversion element 3 when the thermoelectric conversion element 3 to be described later is deformed due to thermal expansion can be controlled by the high thermal expansion layer 11.

In addition, it is preferable that the high thermal expansion layer 11 be formed of a material having lower thermal conductivity than that of the thermoelectric conversion element 3. This makes it possible to suppress the conduction of heat through the high thermal expansion layer 11. Meanwhile, the thermal conductivities [W/mK] of the materials exemplified in the above-described high thermal expansion layer 11 are as follows: aluminum oxide (Al₂O₃: 25 to 36), tin (Sn: 67), magnesium (Mg) alloy (0.11 to 0.17), and polyimide (0.16).

In the thermoelectric conversion device 1C of the present embodiment having such a configuration, as shown in FIG. 10, the heat transferred from the heat source to the heat transfer plate 7 is transferred to each thermoelectric conversion element 3 through the heat transfer portion 7a, so that each thermoelectric conversion element 3 is deformed due to thermal expansion between the first electrode 5a and the second electrode 5b.

In this case, each thermoelectric conversion element 3 is brought into a warped state in the same direction as each other between the first electrode 5a and the second electrode 5b due to a difference in the coefficient of thermal expansion with the high thermal expansion layer 11 provided on its lower surface. That is, since the coefficient of thermal expansion of the thermoelectric conversion element 3 is lower than that of the high thermal expansion layer 11, one end side and the other end side of each thermoelectric conversion element 3 are curved toward the heat transfer plate 7 side. Simultaneously, the second electrode 5b butted to the heat transfer portion 7a of the heat transfer plate 7 is pressed against the heat transfer portion 7a side.

Thereby, in the thermoelectric conversion device 1C of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

Meanwhile, the above thermoelectric conversion device 1C is configured such that, in the configuration of the above thermoelectric conversion device 1B, the high thermal expansion layer 11 is provided at the bottom of the recess 8b instead of the above-described low thermal expansion layer 10, but can also be configured such that, in the configuration of the above thermoelectric conversion device 1A, the high thermal expansion layer 11 is provided at the bottom of the recess 8b instead of the above-described low thermal expansion layer 10.

### Fourth Embodiment

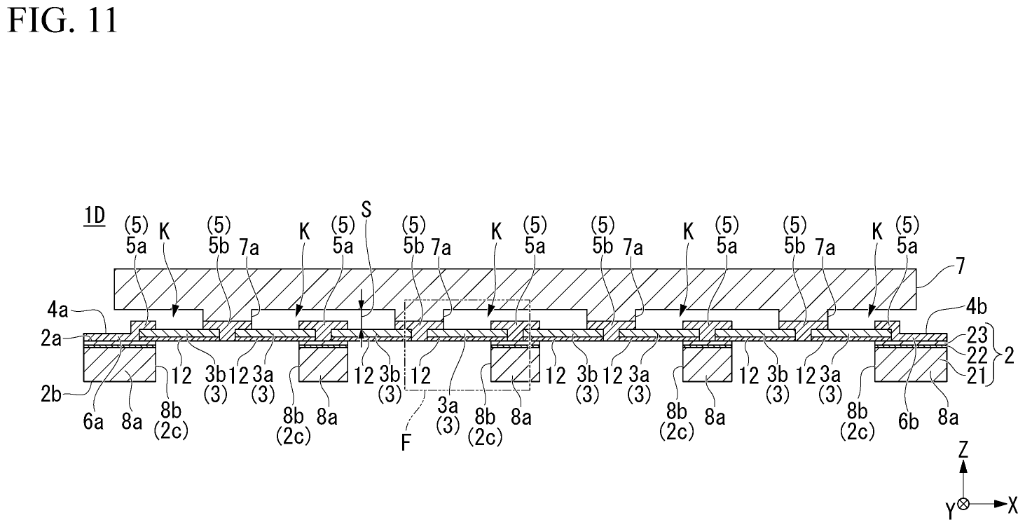

Next, as a fourth embodiment of the disclosure, for example, a thermoelectric conversion device 1D shown in FIGS. 11 to 13 will be described. Meanwhile, FIG. 11 is a cross-sectional view illustrating a schematic configuration of the thermoelectric conversion device 1D.

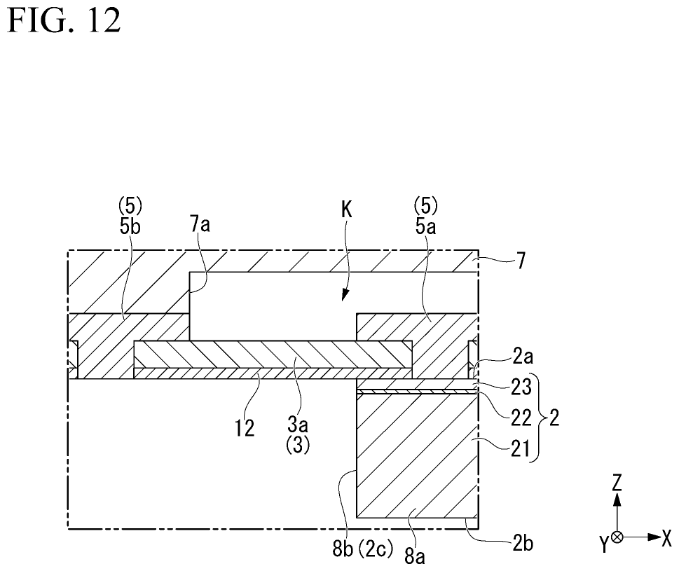

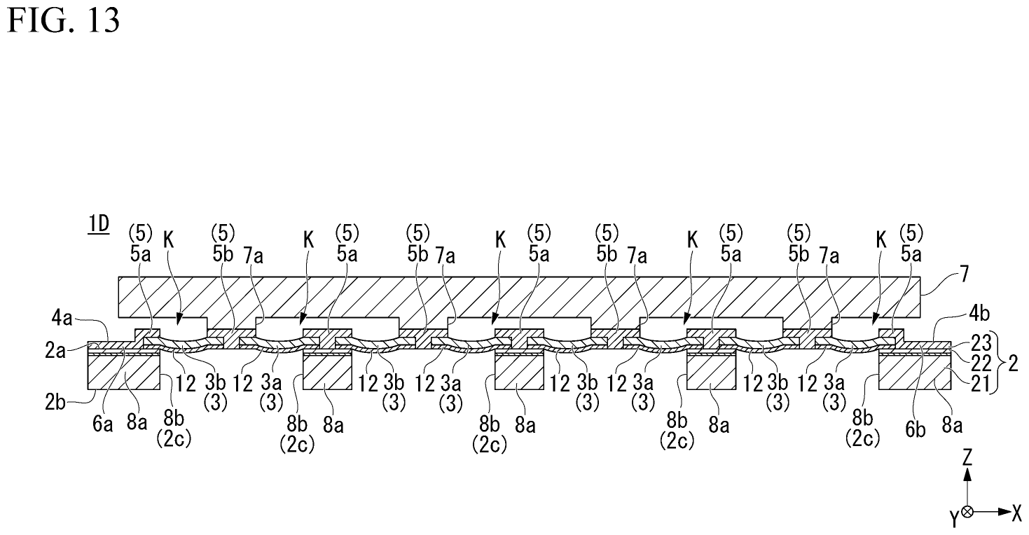

In addition, FIG. 11 is a cross-sectional view of the thermoelectric conversion device 1D corresponding to segment A-A shown in FIG. 1. FIG. 12 is an enlarged cross-sectional view illustrating main parts of a surrounded portion E shown in FIG. 11. FIG. 13 is a cross-sectional view illustrating a state in which each thermoelectric conversion element 3 of the thermoelectric conversion device 1D is deformed due to thermal expansion.

In addition, in the following description, the same parts as those in the above thermoelectric conversion device 1B will not be described, and are assumed to be denoted by the same reference numerals and signs in the drawings.

As shown in FIG. 11, the thermoelectric conversion device 1D of the present embodiment has basically the same configuration as that of the above thermoelectric conversion device 1B, except that a high thermal expansion layer 12 is provided instead of the above-described low thermal expansion layer 10.

Specifically, as shown in an enlarged view in FIG. 12, the thermoelectric conversion device 1D of the present embodiment has a configuration in which the high thermal expansion layer 12 is provided on the surface side of each thermoelectric conversion element 3 facing the recess 8b.

The high thermal expansion layer 12 is formed of a material having a higher coefficient of thermal expansion than that of the thermoelectric conversion element 3. Therefore, regarding the high thermal expansion layer 12, a material having a higher coefficient of thermal expansion than that of the thermoelectric conversion element 3 can be selected and used from the materials and the like exemplified in the above high thermal expansion layer 11.

In the thermoelectric conversion device 1D of the present embodiment, similarly to the above thermoelectric conversion device 1B, a region corresponding to the recess 8b is provided with a hole portion 2c penetrating through the substrate 2, so that a portion of the high thermal expansion layer 12 and the first electrode 5a are located at the bottom of the recess 8b.

The high thermal expansion layer 12 of the present embodiment is located between the substrate 2 and the thermoelectric conversion element 3, and is provided so as to cover the lower surface of the thermoelectric conversion element 3. That is, in the present embodiment, the thermoelectric conversion device is provided in a state in which the high thermal expansion layer 12 and the thermoelectric conversion element 3 are laminated on the first surface 2a side of the substrate 2.

In addition, it is preferable that the thickness of the high thermal expansion layer 12 be smaller than the thickness of the thermoelectric conversion element 3.

By reducing the thickness of the high thermal expansion layer 12, it is possible to suppress the conduction of heat through this high thermal expansion layer 12.

Specifically, the thickness of the high thermal expansion layer 12 is preferably equal to or greater than 1/200 times and equal to or less than ⅕ times (0.005 to 0.2 times), and more preferably equal to or greater than 1/100 times and equal to or less than 1/10 times (0.01 to 0.1 times) the thickness of the thermoelectric conversion element 3. Thereby, while suppressing the conduction of heat through the high thermal expansion layer 12, the deformation direction of the thermoelectric conversion element 3 when the thermoelectric conversion element 3 to be described later is deformed due to thermal expansion can be controlled by the high thermal expansion layer 12.

In addition, it is preferable that the high thermal expansion layer 12 be formed of a material having lower thermal conductivity than that of the thermoelectric conversion element 3 similarly to the above-described high thermal expansion layer 11. This makes it possible to suppress the conduction of heat through the high thermal expansion layer 12.

In the thermoelectric conversion device 1D of the present embodiment having such a configuration, as shown in FIG. 13, the heat transferred from the heat source to the heat transfer plate 7 is transferred to each thermoelectric conversion element 3 through the heat transfer portion 7a, so that each thermoelectric conversion element 3 is deformed due to thermal expansion between the first electrode 5a and the second electrode 5b.

In this case, each thermoelectric conversion element 3 is brought into a warped state in the same direction as each other between the first electrode 5a and the second electrode 5b due to a difference in the coefficient of thermal expansion with the high thermal expansion layer 12 provided on its lower surface. That is, since the coefficient of thermal expansion of the thermoelectric conversion element 3 is lower than that of the high thermal expansion layer 12, one end side and the other end side of each thermoelectric conversion element 3 are curved toward the heat transfer plate 7 side. Simultaneously, the second electrode 5b butted to the heat transfer portion 7a of the heat transfer plate 7 is pressed against the heat transfer portion 7a side.

Thereby, in the thermoelectric conversion device 1D of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

Meanwhile, the above thermoelectric conversion device 1D is configured such that, in the configuration of the above thermoelectric conversion device 1B, the high thermal expansion layer 12 is provided between the substrate 2 and the thermoelectric conversion element 3 instead of the above-described low thermal expansion layer 10, but can also be configured such that, in the configuration of the above thermoelectric conversion device 1A, the high thermal expansion layer 12 is provided between the substrate 2 and the thermoelectric conversion element 3 instead of the above-described low thermal expansion layer 10.

### Fifth Embodiment

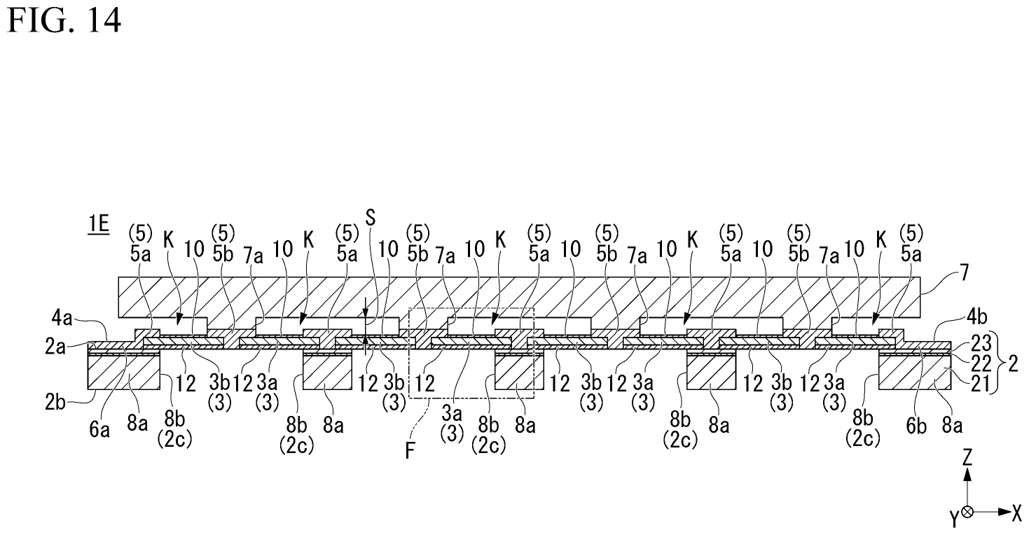

Next, as a fifth embodiment of the disclosure, for example, a thermoelectric conversion device 1E shown in FIGS. 14 to 16 will be described. Meanwhile, FIG. 14 is a cross-sectional view illustrating a schematic configuration of the thermoelectric conversion device 1E.

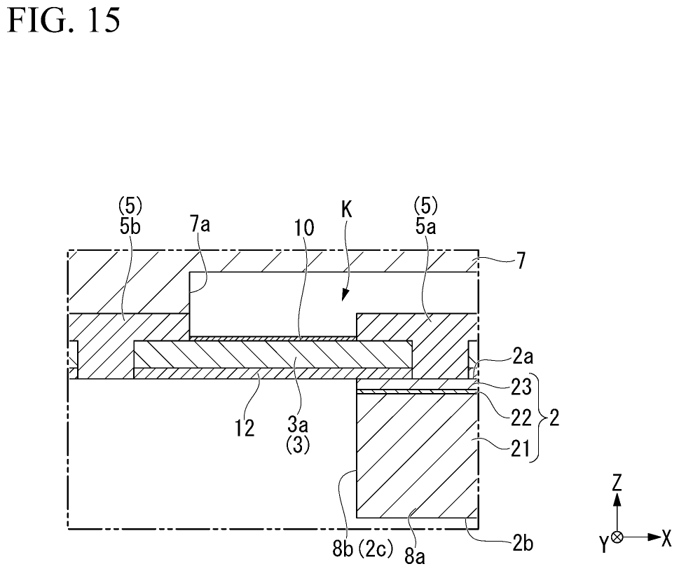

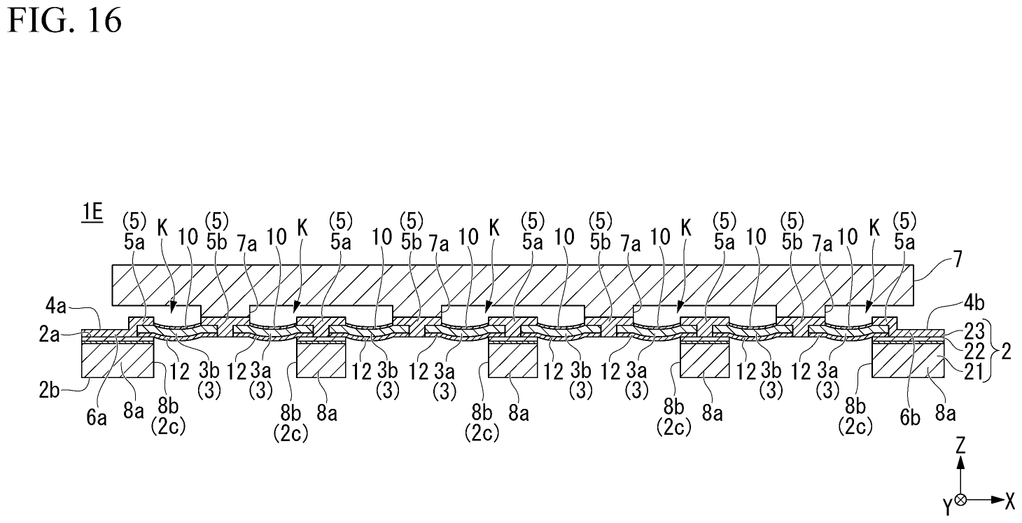

In addition, FIG. 14 is a cross-sectional view of the thermoelectric conversion device 1E corresponding to segment A-A shown in FIG. 1. FIG. 15 is an enlarged cross-sectional view illustrating main parts of a surrounded portion F shown in FIG. 14. FIG. 16 is a cross-sectional view illustrating a state in which each thermoelectric conversion element 3 of the thermoelectric conversion device 1E is deformed due to thermal expansion.

In addition, in the following description, the same parts as those in the above thermoelectric conversion devices 1B and 1D will not be described, and are assumed to be denoted by the same reference numerals and signs in the drawings.

As shown in FIG. 14, the thermoelectric conversion device 1E of the present embodiment has basically the same configuration as that of the above thermoelectric conversion devices 1B and 1D, except that the high thermal expansion layer 12 is provided together with the above-described low thermal expansion layer 10. That is, this thermoelectric conversion device 1E has the configuration of the above thermoelectric conversion device 1D added to the configuration of the above thermoelectric conversion device 1B.

Specifically, as shown in an enlarged view in FIG. 15, the thermoelectric conversion device 1E of the present embodiment is configured such that the high thermal expansion layer 12 is provided on the surface side of each thermoelectric conversion element 3 facing the recess 8b, in addition to the configuration of the above thermoelectric conversion device 1B. That is, this thermoelectric conversion device 1E is provided in a state in which the high thermal expansion layer 12, the thermoelectric conversion element 3, and the low thermal expansion layer 10 are laminated on the first surface 2a side of the substrate 2.

In the thermoelectric conversion device 1E of the present embodiment having such a configuration, as shown in FIG. 16, the heat transferred from the heat source to the heat transfer plate 7 is transferred to each thermoelectric conversion element 3 through the heat transfer portion 7a, so that each thermoelectric conversion element 3 is deformed due to thermal expansion between the first electrode 5a and the second electrode 5b.

In this case, each thermoelectric conversion element 3 is brought into a warped state in the same direction as each other between the first electrode 5a and the second electrode 5b due to a difference in the coefficient of thermal expansion between the low thermal expansion layer 10 provided on its upper surface and the high thermal expansion layer 11 provided on its lower surface. That is, since the coefficient of thermal expansion of the thermoelectric conversion element 3 is higher than that of the low thermal expansion layer 10, and the coefficient of thermal expansion of the thermoelectric conversion element 3 is lower that of the high thermal expansion layer 11, one end side and the other end side of each thermoelectric conversion element 3 are curved toward the heat transfer plate 7 side. Simultaneously, the second electrode 5b butted to the heat transfer portion 7a of the heat transfer plate 7 is pressed against the heat transfer portion 7a side.

Thereby, in the thermoelectric conversion device 1E of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

Meanwhile, the above thermoelectric conversion device 1E is configured such that the high thermal expansion layer 12 is provided between the substrate 2 and the thermoelectric conversion element 3 in addition to the configuration of the above thermoelectric conversion device 1B, but can also be configured such that the high thermal expansion layer 12 is provided between the substrate 2 and the thermoelectric conversion element 3 in addition to the configuration of the above thermoelectric conversion device 1A. Further, the thermoelectric conversion device can also be configured such that the high thermal expansion layer 11 is provided at the bottom of the recess 8b in addition to the configuration of the above thermoelectric conversion device 1A instead of the above high thermal expansion layer 12, or configured such that the high thermal expansion layer 11 is provided at the bottom of the recess 8b in addition to the configuration of the above thermoelectric conversion device 1B.

### Sixth Embodiment

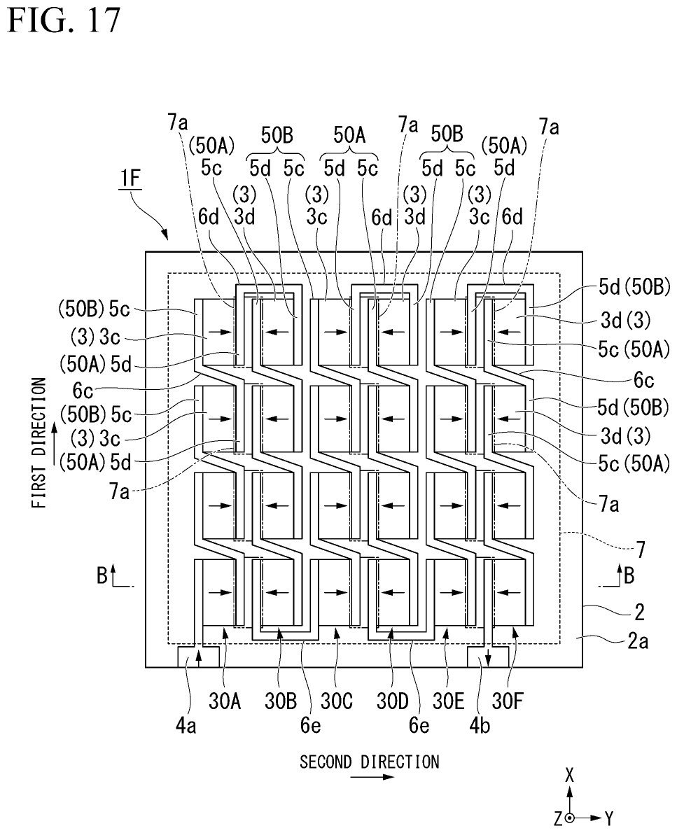

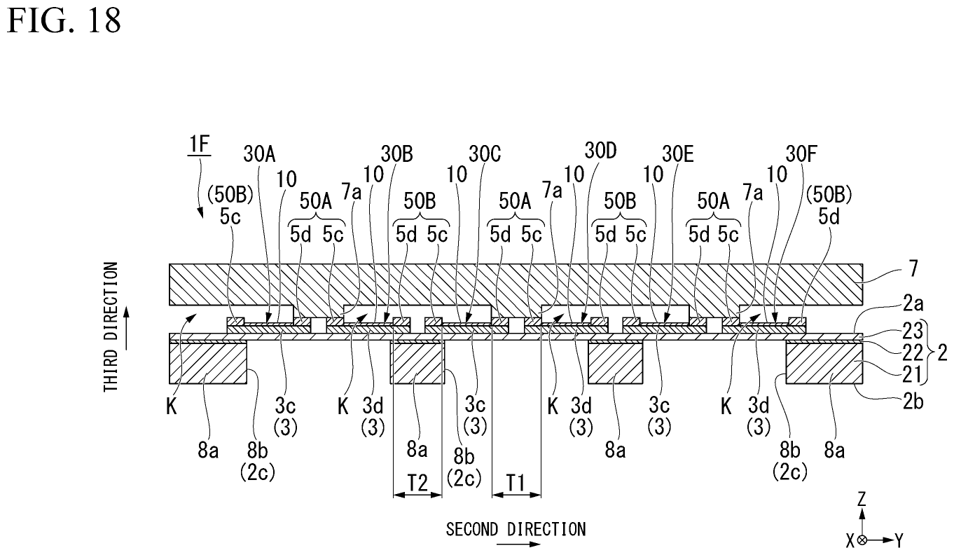

Next, as a sixth embodiment of the disclosure, for example, a thermoelectric conversion device 1F shown in FIGS. 17 and 18 will be described. Meanwhile, FIG. 17 is a perspective plan view illustrating a schematic configuration of the thermoelectric conversion device 1F. FIG. 18 is a cross-sectional view illustrating a schematic configuration of the thermoelectric conversion device 1F. In addition, in the following description, the same parts as those in the above thermoelectric conversion device 1A will not be described, and are assumed to be denoted by the same reference numerals and signs in the drawings.

The thermoelectric conversion device 1F of the present embodiment includes a plurality of (four in the present embodiment) thermoelectric conversion elements 3 lined up in the first direction out of the first direction (X-axis direction) and the second direction (Y-axis direction) that intersect each other (that are orthogonal to each other in the present embodiment) in a plane on the first surface 2a side of the substrate 2, and is provided with a plurality of (six in the present embodiment) thermoelectric conversion element arrays 30A to 30F disposed in a row in the second direction. A plurality of thermoelectric conversion elements 3 are formed of a thermoelectric conversion film which is any one (an n-type semiconductor in the present embodiment) of an n-type semiconductor or a p-type semiconductor.

The thermoelectric conversion device 1F includes a third electrode 5c provided on one end side (−Y side) of each of the thermoelectric conversion elements 3 constituting the thermoelectric conversion element arrays 30A to 30F in the second direction and a fourth electrode 5d provided on the other end side (+Y side) of each of the thermoelectric conversion elements 3 in the second direction. Meanwhile, as materials of the third electrode 5c and the fourth electrode 5d, it is possible to use the same materials as those exemplified in the above-described electrode 5.

In addition, the third electrode 5c (or the fourth electrode 5d) provided in one thermoelectric conversion element 3 and the fourth electrode 5d (or the third electrode 5c) provided in the other thermoelectric conversion element 3 are disposed between one thermoelectric conversion element 3 and the other thermoelectric conversion element 3 which are next to each other in the second direction in a state in which these electrodes are separated from each other.

The thermoelectric conversion device 1F includes a thermoelectric conversion element 3 (hereinafter, distinguished by a “third thermoelectric conversion element 3c” as necessary) in which a current flows from the third electrode 5c side toward the fourth electrode 5d side and a thermoelectric conversion element 3 (hereinafter, distinguished by a “fourth thermoelectric conversion element 3d” as necessary) in which a current flows from the fourth electrode 5d side toward the third electrode 5c side, among the plurality of thermoelectric conversion elements 3.

Meanwhile, in FIG. 17, the direction of a current flowing to the third thermoelectric conversion element 3c, the direction of a current flowing to the fourth thermoelectric conversion element 3d, the direction of a current flowing to one terminal 4a, and the direction of a current flowing to the other terminal 4b are indicated by the directions of arrows.

In the thermoelectric conversion device 1F of the present embodiment, the thermoelectric conversion element arrays 30A, 30C, and 30E are constituted by a plurality of third thermoelectric conversion elements 3c, and the thermoelectric conversion element arrays 30B, 30D, and 30F are constituted by a plurality of fourth thermoelectric conversion elements 3d.

One terminal 4a out of the pair of terminals 4a and 4b is electrically connected to the third electrode 5c of the thermoelectric conversion element 3 (the third thermoelectric conversion element 3c) located on one endmost side (the −X side) in the first direction among the thermoelectric conversion elements 3 constituting the thermoelectric conversion element array 30A located on one endmost side (−Y side) in the second direction.

On the other hand, the other terminal 4b is electrically connected to the third electrode 5c of the thermoelectric conversion element 3 (the fourth thermoelectric conversion element 3d) located on one endmost (the −X side) in the first direction among the thermoelectric conversion elements 3 constituting the thermoelectric conversion element array 30F located on the other endmost side (+Y side) in the second direction.

The thermoelectric conversion device 1F of the present embodiment includes a plurality of third wirings 6c that connect a plurality of thermoelectric conversion elements 3 constituting each of the thermoelectric conversion element arrays 30A to 30F in series to each other, and a plurality of fourth wirings 6d and 6e that connect a plurality of thermoelectric conversion elements arrays 30A to 30F in series to each other so that a plurality of thermoelectric conversion elements 3 constituting one thermoelectric conversion element array next to each other in the second direction among a plurality of thermoelectric conversion elements arrays 30A to 30F and a plurality of thermoelectric conversion elements 3 constituting the other thermoelectric conversion element array are connected in series to each other. Meanwhile, as materials of the third wiring 6c and the fourth wirings 6d and 6e, it is possible to use the same materials as those exemplified in the above-described electrode 5.

The thermoelectric conversion device 1F includes the third electrode 5c or the fourth electrode 5d (hereinafter, referred to as a “hot-junction-side electrode 50A” collectively) serving as a hot junction side and the fourth electrode 5d or the third electrode 5c (hereinafter, referred to as a “cold-junction-side electrode 50B” collectively) serving as a cold junction side which are provided in each of the thermoelectric conversion elements 3 constituting the thermoelectric conversion element arrays 30A to 30F.

The hot-junction-side electrode 50A is constituted by the fourth electrode 5d provided in the third thermoelectric conversion element 3c and the third electrode 5c provided in the fourth thermoelectric conversion element 3d. On the other hand, the cold-junction-side electrode 50B is constituted by the third electrode 5c provided in the third thermoelectric conversion element 3c and the fourth electrode 5d provided in the fourth thermoelectric conversion element 3d.

The hot-junction-side electrode 50A is constituted by the third electrode 5c and the fourth electrode 5d which are next to each other in the second direction. In addition, the cold-junction-side electrode 50B is constituted by the third electrode 5c and the fourth electrode 5d which are next to each other in the second direction.

However, the third electrode 5c provided in the third thermoelectric conversion element 3c located on one endmost side (−Y side) in the second direction and the fourth electrode 5d provided in the fourth thermoelectric conversion element 3d located on the other endmost side (+Y side) in the second direction constitute the cold-junction-side electrode 50B independently of each other.

The heat transfer plate 7 is thermally connected to the hot-junction-side electrode 50A with the heat transfer portion 7a interposed therebetween. The heat transfer portion 7a is constituted by a protrusion projected from any one surface side out of surfaces of the heat transfer plate 7 and the hot-junction-side electrode 50A which face each other. The heat transfer portion 7a of the present embodiment is constituted by a protrusion projected from the position of the heat transfer plate 7 facing each hot-junction-side electrode 50A toward a downward direction (−Z direction) which is the thermoelectric conversion element 3 side.

Each heat transfer portion 7a has a right-angled quadrilateral shape (a rectangular shape in the present embodiment) in a plan view, and is projected inclusive of a range T1 of overlapping the third electrode 5c and the fourth electrode 5d constituting each hot-junction-side electrode 50A. Each protrusion constituting the heat transfer portion 7a is in a state in which each tip is butted to each hot-junction-side electrode 50A. Thereby, the heat transfer plate 7 is thermally connected to the hot junction side (the +Y side of the third thermoelectric conversion element 3c and the −Y side of the fourth thermoelectric conversion element 3d) of the thermoelectric conversion element 3 with the protrusion (heat transfer portion 7a) interposed therebetween. In addition, the tip of each heat transfer portion 7a is thermally connected to each hot-junction-side electrode 50A in a state of being electrically insulated therefrom with an insulating layer (not shown) interposed therebetween.

A space K serving as an air layer is provided between the substrate 2 and the heat transfer plate 7. In addition, the space K is partitioned between the heat transfer portions 7a next to each other. That is, the space K is provided between each thermoelectric conversion element 3 and the cold-junction-side electrode SOB and the heat transfer plate 7.

In the thermoelectric conversion device 1F of the present embodiment, the first surface 2a of the substrate 2 is planar, while the second surface 2b of the substrate 2 is provided with a plurality of (four in the present embodiment) protrusions 8a a plurality of (three in the present embodiment) recesses 8b which are lined up alternately in the second direction.

The plurality of protrusions 8a are projected at a constant height inclusive of a range T2 of overlapping each cold-junction-side electrode 50B in a plan view. The plurality of recesses 8b are recessed at a constant depth over between the plurality of protrusions 8a. That is, the plurality of recesses 8b are recessed in a range of a region overlaps with interspaces between a plurality of cold-junction-side electrodes 50B in a plan view. In the present embodiment, similarly to the case shown in FIG. 3, the recess 8b having a depth reaching the above-described thin-film Si layer 23 is provided.

In the thermoelectric conversion device 1F of the present embodiment, a low thermal expansion layer 10 is provided on the surface (upper surface in the present embodiment) side of each thermoelectric conversion element 3 facing the heat transfer plate 7. The low thermal expansion layer 10 is formed in a right-angled quadrilateral shape (a rectangular shape in the present embodiment) in a plan view on the surface of each thermoelectric conversion element 3. In the present embodiment, the low thermal expansion layer 10 is provided between the third electrode 5c and the fourth electrode 5d so as to cover the upper surface of the thermoelectric conversion element 3.

In the thermoelectric conversion device 1F having such a configuration, the hot-junction-side electrode 50A side of each thermoelectric conversion element 3 becomes relatively high in temperature due to heat transferred from the heat transfer plate 7 through the heat transfer portion 7a to the hot-junction-side electrode 50A. On the other hand, since heat transferred to each thermoelectric conversion element 3 is emitted from the cold-junction-side electrode 50B through the protrusion 8a of the substrate 2 to the outside, the cold-junction-side electrode 50B side of each thermoelectric conversion element 3 becomes relatively low in temperature. Therefore, a difference in temperature occurs between the hot-junction-side electrode 50A and the cold-junction-side electrode 50B of each thermoelectric conversion element 3.

Thereby, the movement of electric charge (carrier) occurs between the third electrode 5c and the fourth electrode 5d of each thermoelectric conversion element 3. That is, an electromotive force (voltage) due to a Seebeck effect is generated between the third electrode 5c and the fourth electrode 5d of each thermoelectric conversion element 3.

Here, in the thermoelectric conversion device 1F of the present embodiment, the plurality of third wirings 6c that connect a plurality of thermoelectric conversion elements 3 constituting each of the above-described thermoelectric conversion element arrays 30A to 30F in series to each other, and the plurality of fourth wirings 6d and 6e that connect a plurality of thermoelectric conversion elements arrays 30A to 30F in series to each other so that the plurality of thermoelectric conversion elements 3 constituting one thermoelectric conversion element array next to each other in the second direction among a plurality of thermoelectric conversion elements arrays 30A to 30F and a plurality of thermoelectric conversion elements 3 constituting the other thermoelectric conversion element array are connected in series to each other are drawn around between the pair of terminals 4a and 4b. Therefore, a relatively high voltage can be extracted from between the pair of terminals 4a and 4b as the total electromotive force.

Incidentally, in the thermoelectric conversion device 1F of the present embodiment, the low thermal expansion layer 10 having a lower coefficient of thermal expansion than that of the thermoelectric conversion element 3 is provided on the surface side of each thermoelectric conversion element 3 described above which faces the heat transfer plate 7. In the case of this configuration, similarly to the case shown in FIG. 4, the heat transferred from the heat source to the heat transfer plate 7 is transferred to each thermoelectric conversion element 3 through the heat transfer portion 7a, so that each thermoelectric conversion element 3 is deformed due to thermal expansion between the third electrode 5c and the fourth electrode 5d.

In this case, each thermoelectric conversion element 3 is brought into a warped state in the same direction as each other between the third electrode 5c and the fourth electrode 5d due to a difference in the coefficient of thermal expansion with the low thermal expansion layer 10 provided on its upper surface. That is, since the coefficient of thermal expansion of the thermoelectric conversion element 3 is higher than that of the low thermal expansion layer 10, one end side and the other end side of each thermoelectric conversion element 3 are curved toward the heat transfer plate 7 side. Simultaneously, the hot-junction-side electrode 50A (the third electrode 5c and the fourth electrode 5d) butted to the heat transfer portion 7a of the heat transfer plate 7 is pressed against the heat transfer portion 7a side.

Thereby, in the thermoelectric conversion device 1F of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

### Seventh Embodiment

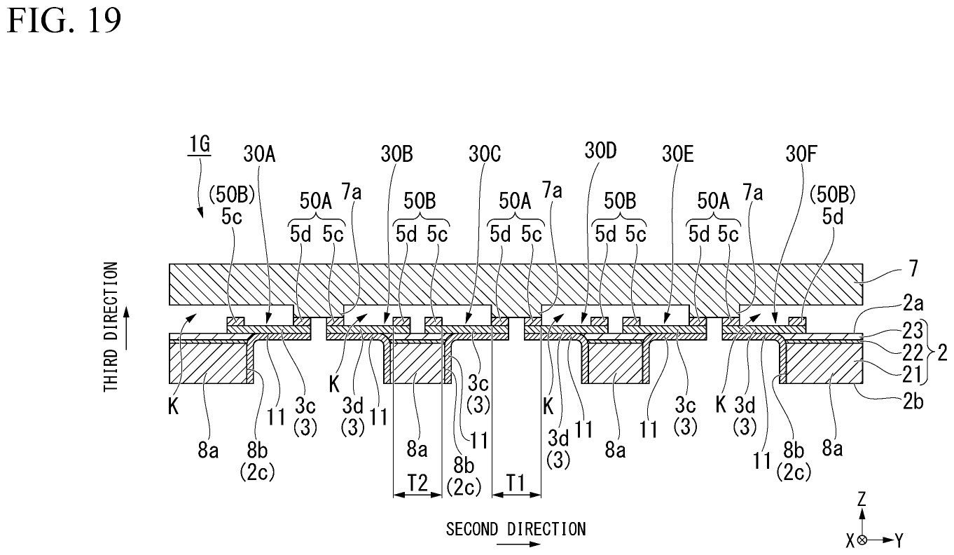

Next, as a seventh embodiment of the disclosure, for example, a thermoelectric conversion device 1G shown in FIG. 19 will be described. Meanwhile, FIG. 19 is a cross-sectional view illustrating a schematic configuration of the thermoelectric conversion device 1G. In addition, in the following description the same parts as those in the above thermoelectric conversion devices 1C and 1F will not be described, and are assumed to be denoted by the same reference numerals and signs in the drawings.

As shown in FIG. 19, the thermoelectric conversion device 1G of the present embodiment has basically the same configuration as that of the above thermoelectric conversion device 1F, except that a high thermal expansion layer 11 is provided instead of the above-described low thermal expansion layer 10.

Specifically, the thermoelectric conversion device 1G of the present embodiment has a configuration in which the high thermal expansion layer 11 is provided on the surface (lower surface in the present embodiment) side of each thermoelectric conversion element 3 facing the recess 8b.

In addition, in the thermoelectric conversion device 1G of the present embodiment, similarly to the case shown in FIG. 9, a region corresponding to the recess 8b is provided with a hole portion 2c penetrating through the substrate 2, so that a portion of the thermoelectric conversion element 3 is located at the bottom of the recess 8b.

The high thermal expansion layer 11 of the present embodiment is located at the bottom of this recess 8b, and is provided so as to cover the bottom of the recess 8b including the lower surface of the thermoelectric conversion element 3 and the lateral side of the recess 8b. On the other hand, the high thermal expansion layer 11 is partitioned between the thermoelectric conversion elements 3 (at a position corresponding to the hot-junction-side electrode 50A) located at the bottom of the recess 8b.

In the thermoelectric conversion device 1G of the present embodiment having such a configuration, similarly to the case shown in FIG. 10, the heat transferred from the heat source to the heat transfer plate 7 is transferred to each thermoelectric conversion element 3 through the heat transfer portion 7a, so that each thermoelectric conversion element 3 is deformed due to thermal expansion between the third electrode 5c and the fourth electrode 5d.

In this case, each thermoelectric conversion element 3 is brought into a warped state in the same direction as each other between the third electrode 5c and the fourth electrode 5d due to a difference in the coefficient of thermal expansion with the high thermal expansion layer 11 provided on its lower surface. That is, since the coefficient of thermal expansion of the thermoelectric conversion element 3 is lower than that of the high thermal expansion layer 11, one end side and the other end side of each thermoelectric conversion element 3 is curved toward the heat transfer plate 7 side. Simultaneously, the hot-junction-side electrode 50A (the third electrode 5c and the fourth electrode 5d) butted to the heat transfer portion 7a of the heat transfer plate 7 is pressed against the heat transfer portion 7a side.

Thereby, in the thermoelectric conversion device 1G of the present embodiment, even in a case where each thermoelectric conversion element 3 is deformed due to thermal expansion, it is possible to secure the thermal connection reliability of each thermoelectric conversion element 3 while aligning a direction in which each thermoelectric conversion element 3 is deformed.

Meanwhile, the present invention is not necessarily limited to the above-described embodiments, and can have various changes and modifications added thereto without departing from the spirit and scope of the disclosure.

For example, in the above thermoelectric conversion devices 1A to 1E, a case in which the heat transfer plate 7 is disposed on the high-temperature (heat source) side and the substrate 2 is disposed on the low-temperature (heat dissipation/cooling) side is illustrated, but the substrate 2 can be disposed on the high-temperature (heat source) side and the heat transfer plate 7 can be disposed on the low-temperature (heat dissipation/cooling) side, whereby heat from the heat source may be transferred from the substrate 2 side. In this case, the first electrode 5a serves as a hot-junction-side electrode, and the second electrode 5b serves as a cold-junction-side electrode.

In addition, the above thermoelectric conversion device 1A to 1E is configured such that the second electrode (one electrode) 5b and the heat transfer plate 7 described above are thermally connected to each other through the heat transfer portion 7a, and that the recess 8b is provided in a range of a region overlaps with interspaces between the first electrodes (the other electrodes) 5a in a plan view, but on the contrary, may be configured such that the first electrode (one electrode) 5a and the heat transfer plate 7 are thermally connected to each other through the heat transfer portion 7a, and that the recess 8b is provided in a range of a region overlaps with interspaces between the second electrodes (the other electrodes) 5b in a plan view.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the disclosure. Accordingly, the invention is not to be considered as being limited by the foregoing description, and is only limited by the scope of the appended claims.

What is claimed is:

1. A thermoelectric conversion device, comprising:
a base material having a first surface and a second surface that face each other in a thickness direction;
thermoelectric conversion elements provided in a row in a plane on the first surface side of the base material;
electrodes, each of which is provided on one end side or other end side of each of the thermoelectric conversion elements in a direction of the row of the thermoelectric conversion elements;
a heat transfer member disposed on the first surface side of the base material with an interval from at least a part of the thermoelectric conversion elements; and
heat transfer portions, each of which is configured to thermally connect: one electrode provided on one side of a hot junction side and a cold junction side of each of the thermoelectric conversion elements; and the heat transfer member,
wherein the base material has recesses on the second surface side, the recesses being provided so as to be recessed in a range of a region which overlaps with interspaces between other electrodes provided on other side of the hot junction side and the cold junction side of each of the thermoelectric conversion elements in a plan view, and
a low thermal expansion layer having a lower coefficient of thermal expansion than that of the thermoelectric conversion element is provided on a surface side of each of the thermoelectric conversion elements facing the heat transfer member.

2. A thermoelectric conversion device, comprising:
a base material having a first surface and a second surface that face each other in a thickness direction;
thermoelectric conversion elements provided in a row in a plane on the first surface side of the base material;
electrodes, each of which is provided on one end side or other end side of each of the thermoelectric conversion elements in a direction of the row of the thermoelectric conversion elements;
a heat transfer member disposed on the first surface side of the base material with an interval from at least a part of the thermoelectric conversion elements; and
heat transfer portions, each of which is configured to thermally connect: one electrode provided on one side of a hot junction side and a cold junction side of each of the thermoelectric conversion elements; and the heat transfer member,
wherein the base material has recesses on the second surface side, the recesses being provided so as to be recessed in a range of a region which overlaps with interspaces between other electrodes provided on other side of the hot junction side and the cold junction side of each of the thermoelectric conversion elements in a plan view, and
a high thermal expansion layer having a higher coefficient of thermal expansion than that of the thermoelectric conversion element is provided on a surface side of each of the thermoelectric conversion elements facing the recess.

3. The thermoelectric conversion device according to claim 2, wherein the high thermal expansion layer is located at a bottom of the recess.

4. The thermoelectric conversion device according to claim 2, wherein the high thermal expansion layer is located between the base material and the thermoelectric conversion element.

5. The thermoelectric conversion device according to claim 2, wherein a low thermal expansion layer having a lower coefficient of thermal expansion than that of the thermoelectric conversion element is provided on a surface side of each of the thermoelectric conversion elements facing the heat transfer member.

6. The thermoelectric conversion device according to claim 3, wherein a low thermal expansion layer having a lower coefficient of thermal expansion than that of the thermoelectric conversion element is provided on a surface side of each of the thermoelectric conversion elements facing the heat transfer member.

7. The thermoelectric conversion device according to claim 4, wherein a low thermal expansion layer having a lower coefficient of thermal expansion than that of the thermoelectric conversion element is provided on a surface side of each of the thermoelectric conversion elements facing the heat transfer member.

8. The thermoelectric conversion device according to claim 1, wherein a thickness of the low thermal expansion layer is smaller than a thickness of the thermoelectric conversion element.

9. The thermoelectric conversion device according to claim 5, wherein a thickness of the low thermal expansion layer is smaller than a thickness of the thermoelectric conversion element.

10. The thermoelectric conversion device according to claim 6, wherein a thickness of the low thermal expansion layer is smaller than a thickness of the thermoelectric conversion element.

11. The thermoelectric conversion device according to claim 8, wherein the thickness of the low thermal expansion layer is equal to or greater than 1/200 times and equal to or less than ⅕ times the thickness of the thermoelectric conversion element.

12. The thermoelectric conversion device according to claim 9, wherein the thickness of the low thermal expansion layer is equal to or greater than 1/200 times and equal to or less than ⅕ times the thickness of the thermoelectric conversion element.

13. The thermoelectric conversion device according to claim 2, wherein a thickness of the high thermal expansion layer is smaller than a thickness of the thermoelectric conversion element.

14. The thermoelectric conversion device according to claim 13, wherein the thickness of the high thermal expansion layer is equal to or greater than 1/200 times and equal to or less than ⅕ times the thickness of the thermoelectric conversion element.

15. The thermoelectric conversion device according to claim 1, wherein each of the thermoelectric conversion elements is provided to be able to warp in the same direction as each other between the one electrode and the other electrode during thermal expansion.

16. The thermoelectric conversion device according to claim 2, wherein each of the thermoelectric conversion elements is provided to be able to warp in the same direction as each other between the one electrode and the other electrode during thermal expansion.

17. The thermoelectric conversion device according to claim 1, wherein at least a portion of the thermoelectric conversion element is located at the bottom of the recess.

18. The thermoelectric conversion device according to claim 2, wherein at least a portion of the thermoelectric conversion element is located at the bottom of the recess.

19. The thermoelectric conversion device according to claim 1, wherein the base material is a silicon-on-insulator (SOI) substrate.

20. The thermoelectric conversion device according to claim 2, wherein the base material is a silicon-on-insulator (SOI) substrate.
